(19) United States
(12) Patent Application Publication
(10) Pub. No.: US 2012/0302065 A1
(43) Pub. Date: Nov. 29, 2012

(54) PULSE-PLASMA ETCHING METHOD AND PULSE-PLASMA ETCHING APPARATUS

(75) Inventors: Chih Ching Lin, Taoyuan City (TW); Yi Nan Chen, Taipei City (TW); Hsien Wen Liu, Luzhu Township (TW)

(73) Assignee: NANYA TECHNOLOGY CORPORATION, Kueishan (TW)

(21) Appl. No.: 13/116,164

(22) Filed: May 26, 2011

(51) Int. Cl. H01L 21/3065; C23F 1/08

(52) U.S. Cl. 438/694; 156/345.28; 257/E21.218

(57) ABSTRACT

The present invention relates to a pulse-plasma etching method and apparatus for preparing a depression structure with reduced bowing. The pulse-plasma etching apparatus comprises a container, an upper electrode plate, a lower electrode plate, a gas source, a first ultrahigh RF power supply, a bias RF power supply, and a pulsing module. When the pulsing module supplies an ultrahigh-frequency voltage between the upper electrode plate and the lower electrode plate, an ultrahigh-frequency voltage is switched to the off state, and a large amount of electrons pass through the plasma and reach the substrate to neutralize the positive ions during the duration of the off state (T_{off}).

### TECHNICAL FIELD

The present invention generally relates to a plasma etching method and apparatus. More particularly, the present invention relates to a pulse-plasma etching method and apparatus for preparing a depression structure with reduced bowing.

### BACKGROUND

FIGS. 1 to 3 illustrate the etching steps of a conventional method for preparing a semiconductor device. As shown in FIG. 1, a carbon hard mask 20 is formed on a substrate 10, and the substrate 10 includes an electronic components layer 11, a semiconductor layer 12, and a low-κ dielectric layer 13. The carbon hard mask 20 has a pattern 201 to expose part of the substrate 10.

As shown in FIG. 2, the substrate 10 with the carbon hard mask 20 is placed in a plasma etching apparatus 100. The plasma etching apparatus 100 comprises a container 110, an upper electrode plate 120, a lower electrode plate 130, a gas source 140, a gas exhaust unit 150, an first source RF power supply 160, an first source RF power supply controller 161, a DC power supply 170, a DC power supply controller 171, a bias RF power supply 180, a bias RF power supply controller 181, a second source RF power supply 190 and a second source RF power supply controller 191.

The container 110 includes an upper wall 111 and a lower wall 112, both of which define a processing chamber 113. The upper electrode plate 120 is disposed on the upper wall 111. The lower electrode plate 130 is disposed on the lower wall 112 and includes a chuck 114 for holding the substrate 10. The gas source 140 is connected to the processing chamber 113 for introducing a processing gas into the processing chamber 113. Usually, the gas source 140 comprises an etch gas source 141, a deposition gas source 142 and a gas controller 143. The etch gas source 141 supplies etch gases such as N₂/H₂ or N₂/NH₃ to the processing chamber 113 and the deposition gas source 142 supplies a deposition gas to the processing chamber 113 through the gas controller 143. The gas exhaust unit 150 is used for removing the gas from the processing chamber 113 so as to control the pressure in the processing chamber 113.

The first source RF power supply 160 is controlled by the first source RF power supply controller 161, and is electrically connected to the upper electrode plate 120 for continuously supplying an upper ultrahigh RF power to the upper electrode plate 120 during a plasma etching process. The DC power supply 170 is controlled by the DC power supply controller 171, and is electrically connected to the upper electrode plate 120 for continuously supplying a DC power to the upper electrode plate 120 during the plasma etching process.

The bias RF power supply 180 is controlled by the bias RF power supply controller 181, and the bias RF power supply 180 is electrically connected to the lower electrode plate 130 for continuously supplying a bias RF power to the lower electrode plate 130 so as to generate a plasma in the processing chamber 113 to etch the substrate 10. The second source RF power supply 190 is controlled by the second source RF power supply controller 191, and is electrically connected to the lower electrode plate 130 for continuously supplying a lower ultrahigh RF power to the lower electrode plate 130.

Referring to FIG. 3, in the etching process, at temperatures higher than 20° C., the low-κ dielectric layer 13 of the substrate 10 is etched to form two bowing trenches 19, 19a. The trench 19 partially exposes the electronic components layer 11. The trench 19a has a twisted profile on the electronic components layer 11, and thus is considered a non-qualified trench.

The formation of the trenches 19a, 19 is described as follows. During the etching process, most of the electrons 21b are distributed around the carbon hard mask 20, and a large amount of the positive ions 21a penetrate deeply into the trenches 19a, 19. Because there are too many positive ions 21a on the bottom of the trenches 19a, 19, the trajectories of the following positive ions are bent, which makes the twisting or bowing profile of the trenches 19a, 19. In addition, the unbalanced concentration of the etch gas and the deposition gas also influences the bowing profile of the trenches 19a, 19.

In order to resolve the above-mentioned issues, the DC power supply 170 is used to continuously supply DC power to the upper electrode plate 120 to induce the secondary electron emission. The secondary electrons are expected to pass through the bulk plasma and sheath and enter the trenches 19a, 19 to neutralize the positive ions 21a. However, in fact, the secondary electrons need very high energy to pass through the bulk plasma and sheath, and less than 6% of the secondary electrons are able to reach the substrate 10. Thus, the DC power superposition is not enough to eliminate the twisting or bowing profile of the trenches 19a, 19 when the source RF power supplies 160, 190 are operated at temperatures greater than 20° C.

### SUMMARY

To solve the problems of the above-mentioned prior art, the present invention discloses a pulse-plasma etching apparatus. The pulse-plasma etching apparatus comprises a container, an upper electrode plate, a lower electrode plate, a gas source, a first ultrahigh RF power supply, a bias RF power supply, and a pulsing module. The container includes an upper wall and a lower wall, wherein a processing chamber is defined between the upper wall and the lower wall. The upper electrode plate is disposed on the upper wall, while the lower electrode plate is disposed on the lower wall. The gas source is connected to the processing chamber and introduces a processing gas into the processing chamber. The first ultrahigh RF power supply is electrically connected to the upper electrode plate. The bias RF power supply is electrically connected to the lower electrode plate. The pulsing module is electrically connected to the bias RF power supply and controls the bias RF power supply to discontinuously supply an ultrahigh-frequency voltage between the upper electrode plate and the lower electrode plate.

The present invention is related to a pulse-plasma etching method. The pulse-plasma etching method comprises the steps of: forming a mask on a substrate, wherein the mask has a pattern; placing the substrate with the mask into a plasma etching apparatus, wherein the plasma etching apparatus comprises a container having an upper wall and a lower wall, an upper electrode plate disposed on the upper wall, and a lower electrode plate disposed on the lower wall and holding the substrate; introducing a processing gas into a processing chamber defined by the upper wall and a lower wall; supplying a first ultrahigh RF power and a DC power to the upper electrode plate; and supplying an ultrahigh-frequency voltage to the lower electrode to discontinuously etch the substrate.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIG. 1 to FIG. 3 illustrate the etching steps of a conventional method for preparing a stacked capacitor; and

FIG. 4 to FIG. 9 illustrate the pulse-plasma etching apparatus and the pulse-plasma etching method for reducing the twisting or bowing profile of the trenches according to one embodiment of the present invention.

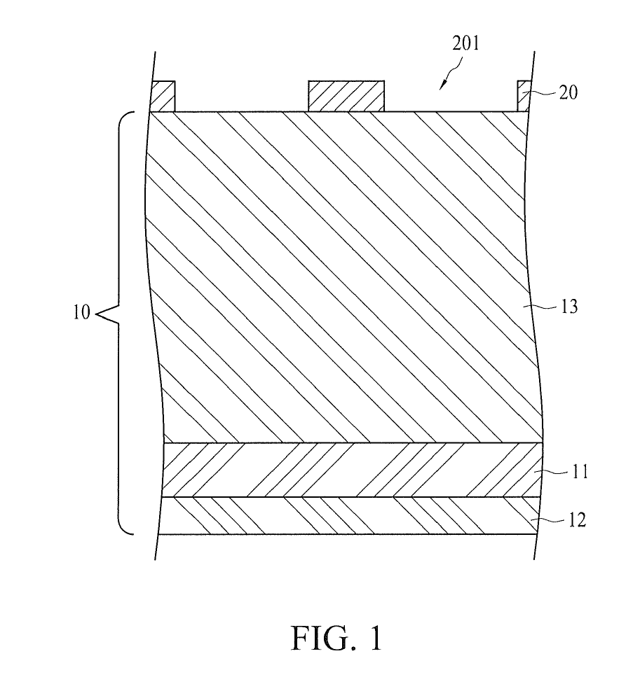

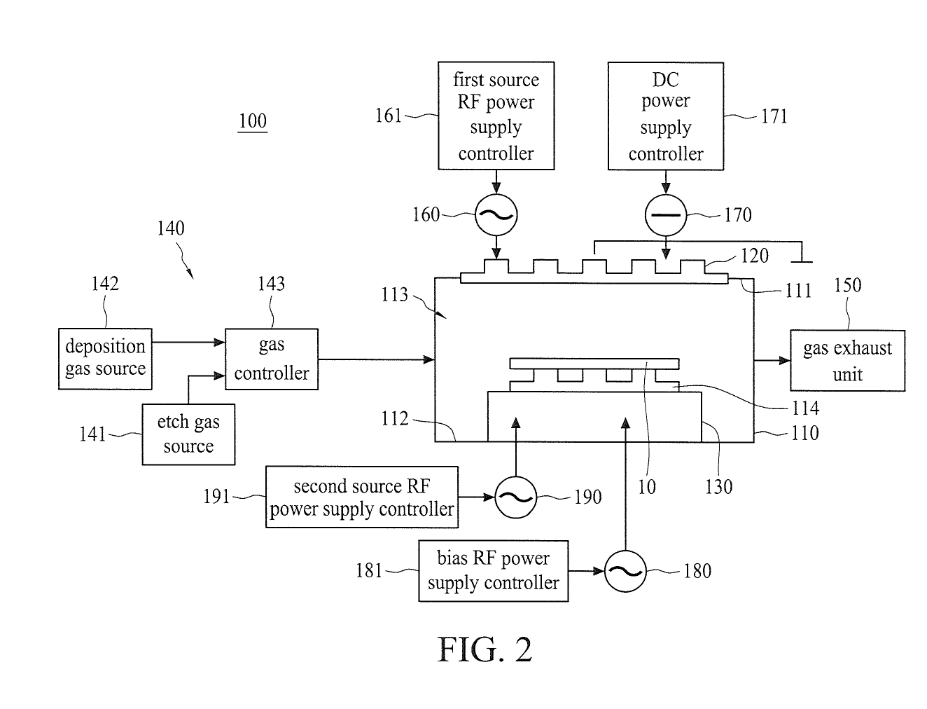

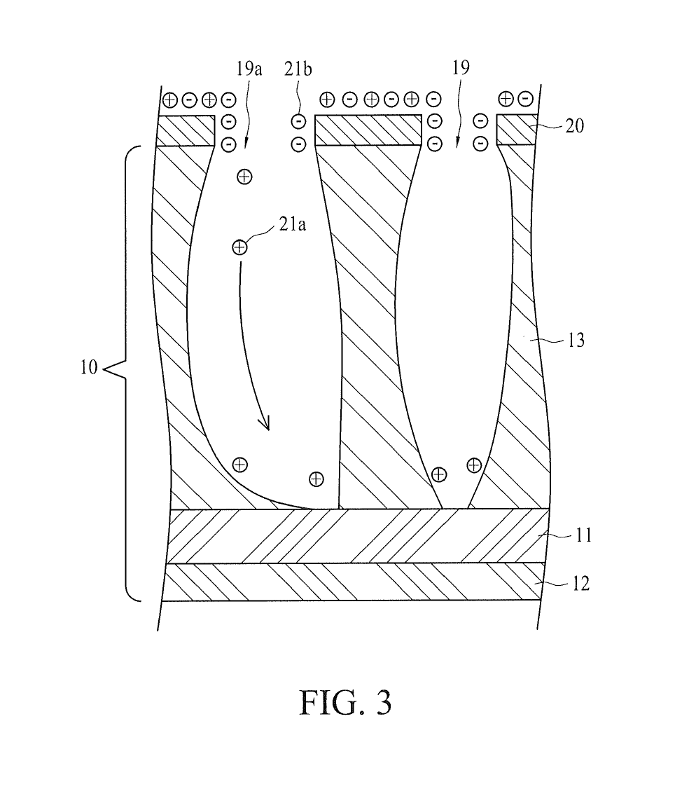

### DETAILED DESCRIPTION

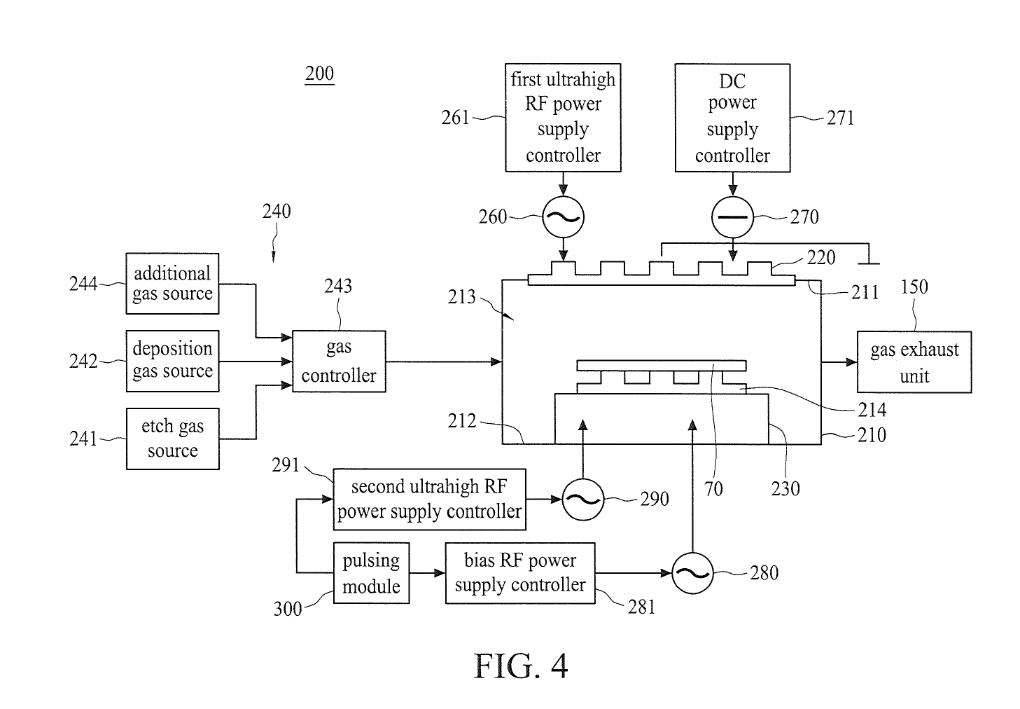

FIG. 4 illustrates a pulse-plasma etching apparatus 200 according to one embodiment of the present invention. The pulse-plasma etching apparatus 200 comprises a container 210, an upper electrode plate 220, a lower electrode plate 230, a gas source 240, a gas exhaust unit 250, a first ultrahigh RF power supply 260, a first ultrahigh RF power supply controller 261, a DC power supply 270, a DC power supply controller 271, a bias RF power supply 280, a bias RF power supply controller 281, a second ultrahigh power supply 290, a second ultrahigh RF power supply controller 291, and a pulsing module 300.

The container 210 includes an upper wall 211 and a lower wall 212. A processing chamber 213 is formed between the upper wall 211 and the lower wall 212. In other words, the upper wall 211 and the lower wall 212 define the processing chamber 213. In this embodiment, the container 210 is electrically grounded. The upper electrode plate 220 is disposed on the upper wall 211 in the processing chamber 213. The lower electrode plate 230 is disposed on the lower wall 212 in the processing chamber 213. In the embodiment shown in FIG. 4, the lower electrode plate 230 further includes a chuck 214 for holding a substrate 70.

The gas source 240 is connected to the processing chamber 213 for introducing a processing gas into the processing chamber 213. In this embodiment, the gas source 240 further includes an etch gas source 241, a deposition gas source 242 and a gas controller 243. The etch gas source 241 supplies an etch gas, such as an N₂/H₂ gas, a Cl₂ gas, a BCl₃ gas, or an HBr gas, to the processing chamber 213. The deposition gas source 243 supplies a deposition gas, such as a CHF₃ gas, or a CF₄ gas, to the processing chamber 213 through the gas controller 243. The processing gas includes the etch gas and the deposition gas. The gas exhaust unit 250 is used for removing the reacted gas from the processing chamber 213 so as to control the pressure in the processing chamber 213.

The first ultrahigh RF power supply 260 is controlled by the first to ultrahigh RF power supply controller 261, and is electrically connected to the upper electrode plate 220 for continuously supplying an upper ultrahigh RF power to the upper electrode plate 220 during a plasma etching process. In other words, the first ultrahigh RF power supply 260 continuously supplies an upper ultrahigh radio frequency voltage to the upper electrode plate 220. In addition, the DC power supply 270 is controlled by the DC power supply controller 271, and is electrically connected to the upper electrode plate 220 for continuously supplying a DC power to the upper electrode plate 220 during the plasma etching process.

The bias RF power supply 280 is controlled by the bias RF power supply controller 281, and is electrically connected to the lower electrode plate 230 for supplying a bias RF power to the lower electrode plate 230 so as to generate a plasma in the processing chamber 213 to etch the substrate 70. The second ultrahigh RF power supply 290 is controlled by the second ultrahigh RF power supply controller 291, and is electrically connected to the lower electrode plate 230 for supplying a lower ultrahigh RF power to the lower electrode plate 230. The lower ultrahigh RF power, which is an ultrahigh radio frequency voltage, may be continuously supplied to the lower electrode plate 230 or supplied synchronously with the bias RF power.

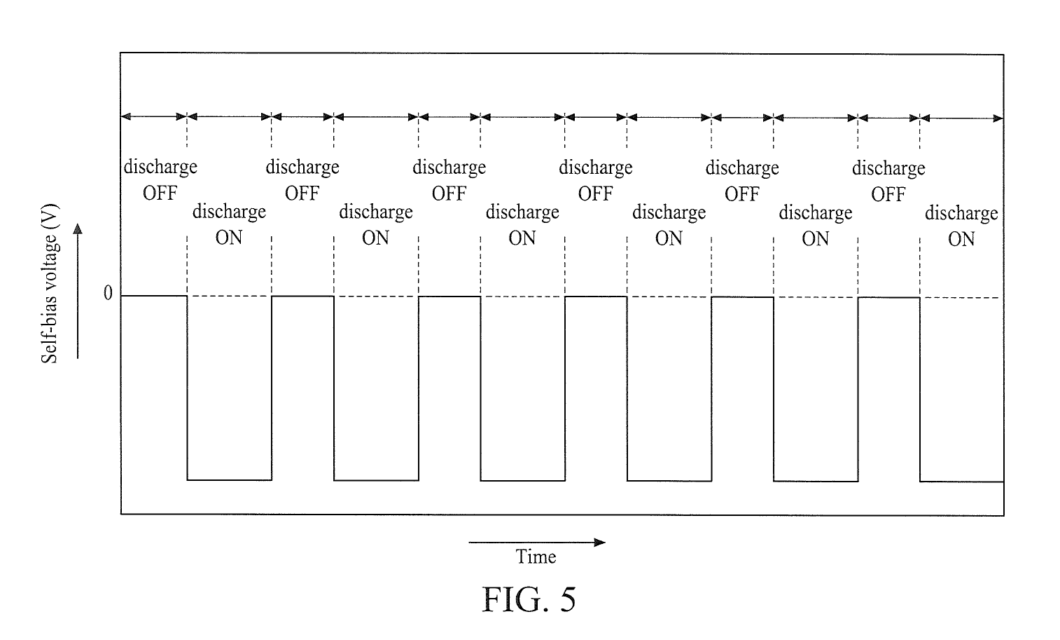

In the embodiment shown in FIG. 4, the pulsing module 300 is electrically connected to the bias RF power supply controller 281, so that an ultrahigh-frequency voltage is discontinuously supplied between the upper electrode plate 220 and the lower electrode plate 230 during the plasma etching process. In other words, the pulsing module 300 controls the bias RF power supply 280 to discontinuously supply the bias RF power such as a ultrahigh-frequency voltage between the upper electrode plate 220 and the lower electrode plate 230. That is, the bias RF power is an ultrahigh-frequency voltage and is alternately switched between on and off states in a very short time, wherein the bias RF power is supplied during the on state and the bias RF power is turned off during the off state. Since the discharge-on and discharge-off states shown in FIG. 5 are established repeatedly and alternately, during the discharge-off state the energy of positive ions as charged particles decreases and thus the trajectories of the following positive ions are not bent. Therefore, the twisting or bowing profile of the trenches can be prevented.

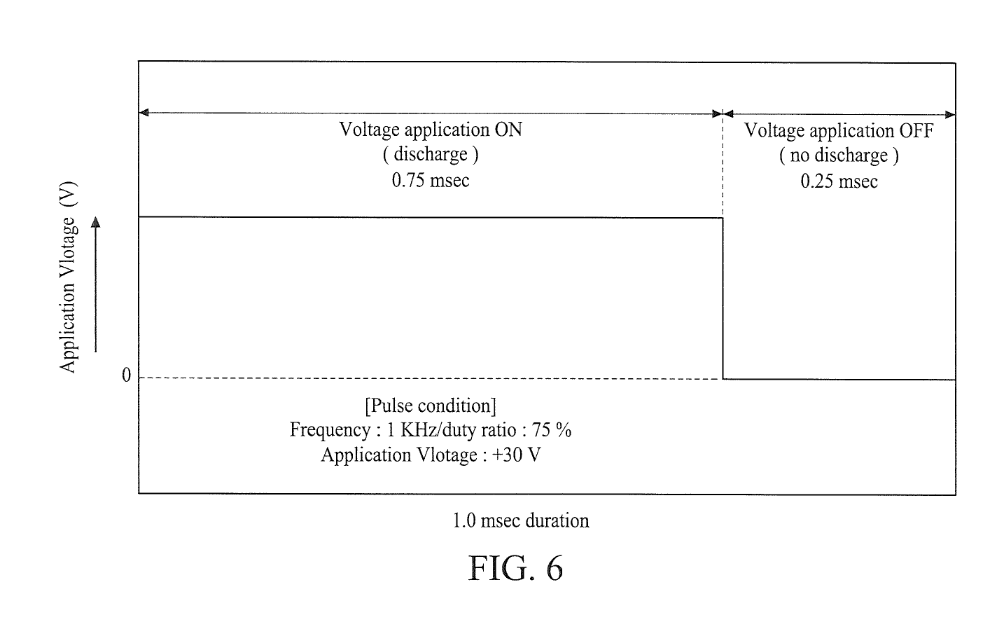

In the embodiment shown in FIG. 4, the duration of the on state (Tₒₙ) is 1 to 100 microseconds, and the duration of the off state (T_{off}) is 1 to 100 microseconds. Preferably, the duration of the on state (Tₒₙ) is equal to the duration of the off state (T_{off}). FIG. 6 shows a more specific example of a manner of pulse modulation in the pulse-plasma etching apparatus 200. The ultrahigh-frequency voltage is alternately switched between on and off states to establish a duty ratio. The duty ratio means a ratio of the discharge period to the entire period that consists of the discharge period (voltage application ON) and the suspension period (voltage application OFF), that is, (discharge period)/(discharge period plus suspension period). In the example shown in FIG. 6, the pulsed discharges having a pulse frequency of 1 kHz and a duty ratio of 75%, a discharge of 0.75 microsecond and suspension of 0.25 microsecond are repeated.

Additionally, in another embodiment (not shown), the pulsing module 300 may be electrically connected to the second ultrahigh RF power supply 290, so that the lower ultrahigh RF power is discontinuously supplied to the lower electrode plate 230 during the plasma etching process, and the lower ultrahigh RF power is supplied synchronously with the bias RF power.

Referring to FIG. 4 again, the pulse-plasma etching apparatus 200 further includes an additional gas source 244 connected to the processing chamber 213 through the gas controller 243. When the bias RF power is switched to the off state, the processing gas is immediately removed from the processing chamber 213 by the gas exhaust unit 250, and an additional gas is introduced into the processing chamber 213 by the additional gas source 244. The additional gas can provide the secondary electrons and acts as a purge gas to reduce the processing gas in the processing chamber 213. The additional gas may be selected from the group consisting of Ar, He, Xe, N₂, H₂ and the combination thereof. Therefore, the gas exhaust unit 250 includes a high performance pumping system for evacuating the processing gas.

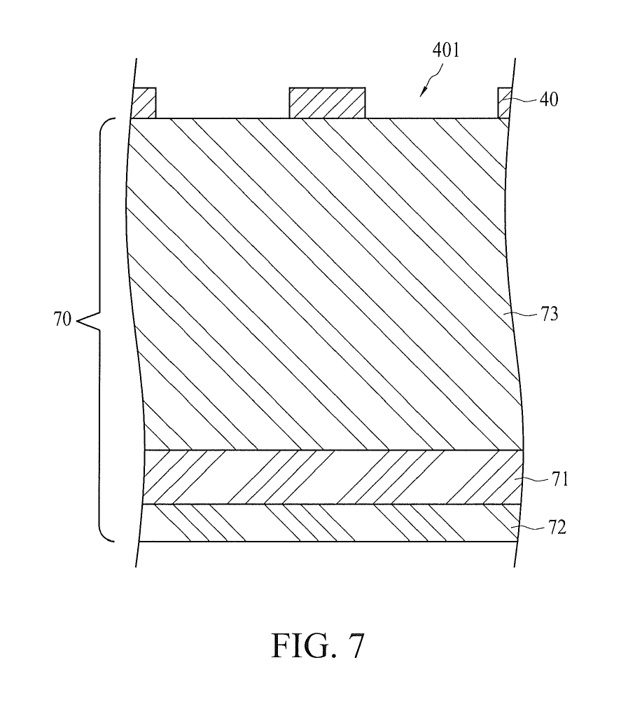

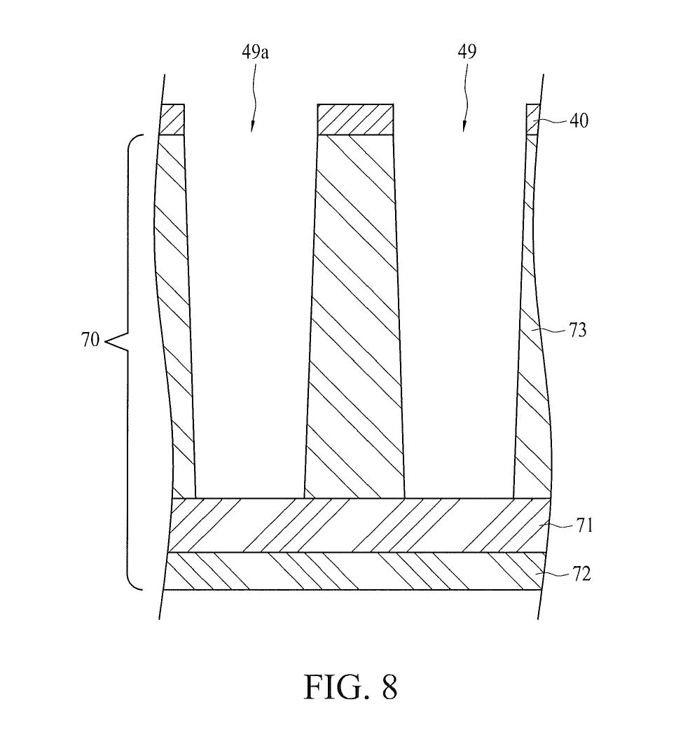

As shown in FIG. 7, a substrate 70 is provided. The substrate 70 includes an electronic components layer 71, a semiconductor layer 72, and a low-κ dielectric layer 73. A carbon hard mask 40 is applied on the substrate 70. The carbon hard mask 40 has a pattern 401 to expose part of the substrate 70. While the chuck 214 holds the substrate 70, the substrate 70 is etched by the plasma in the processing chamber 213 at a temperature greater than 20° C. In the embodiment shown in FIG. 8, when the bias RF power is switched to the off state, a large amount of electrons pass through the plasma and reach the bottom of the trenches 49, 49a to neutralize the positive ions during the duration of the off state (T_{off}). Therefore, the twisting or bowing profile of the trenches 49, 49a can be prevented.

Referring to FIG. 8, in the etching process, the low-κ dielectric layer 73 of the substrate 70 is etched to form two trenches 49, 49a. It should be understood that the above-mentioned pulse-plasma etching method and pulse-plasma etching apparatus are used for forming the trenches 49, 49a with high-aspect-ratio in a semiconductor substrate 70; however, they may be used for forming other structures with high-aspect-ratio, such as holes, in a substrate 70.

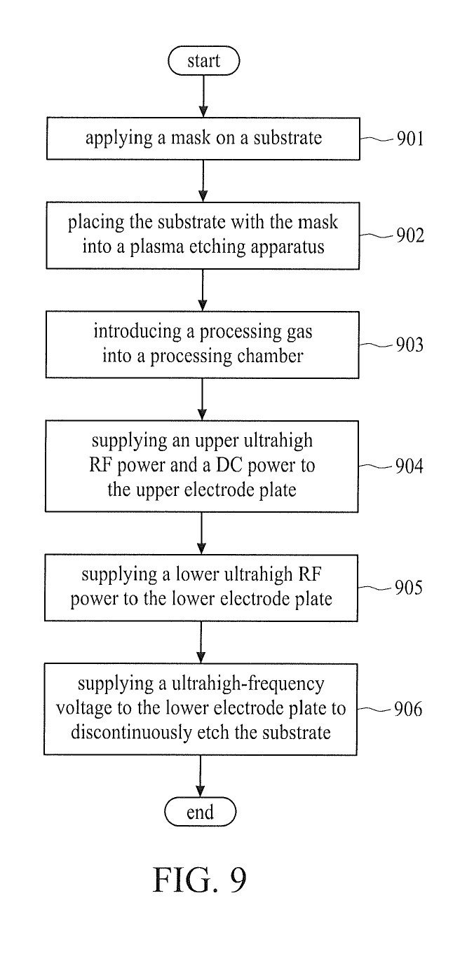

In conclusion, as shown in FIG. 9, the present invention provides a pulse-plasma etching method comprising the following steps: In step 901, a mask is applied on a substrate, wherein the mask has a pattern, and step 902 is executed. In step 902, the substrate with the mask is placed into a plasma etching apparatus, wherein the plasma etching apparatus comprises a container, an upper electrode plate, and a lower electrode plate, the container has an upper wall and a lower wall, the upper electrode plate is disposed on the upper wall, and the lower electrode plate is disposed on the lower wall and holds the substrate, and step 903 is executed. In step 903, a processing gas is introduced into a processing chamber, defined by the upper wall and the lower wall, and step 904 is executed. In step 904, an upper ultrahigh RF power and a DC power are supplied to the upper electrode plate, and step 905 is executed. In step 905, a lower ultrahigh RF power is supplied to the lower electrode plate, and step 906 is executed. In step 906, an ultrahigh-frequency voltage is supplied to the lower electrode plate to discontinuously etch the substrate. Accordingly, the twisting or bowing profile of the trenches can be prevented.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A pulse-plasma etching apparatus, comprising:
a container, including an upper wall and a lower wall, wherein a processing chamber is defined between the upper wall and the lower wall;
an upper electrode plate, disposed on the upper wall;
a lower electrode plate, disposed on the lower wall;
a gas source, connected to the processing chamber and introducing a processing gas into the processing chamber;
a first ultrahigh RF power supply, electrically connected to the to upper electrode plate;
a bias RF power supply, electrically connected to the lower electrode plate; and
a pulsing module, electrically connected to the bias RF power supply and controlling the bias RF power supply to discontinuously supply an ultrahigh-frequency voltage between the upper electrode plate and the lower electrode plate.

2. The pulse-plasma etching apparatus of claim 1, wherein the gas source includes an etch gas source and a deposition gas source, and the processing gas includes an etch gas and a deposition gas.

3. The pulse-plasma etching apparatus of claim 1, further comprising a second ultrahigh RF power supply electrically connected to the lower electrode plate for supplying a lower ultrahigh RF power to the lower electrode plate, wherein the lower ultrahigh RF power is supplied synchronously with the bias RF power.

4. The pulse-plasma etching apparatus of claim 1, wherein the ultrahigh-frequency voltage is alternately switched between on and off states, the ultrahigh-frequency voltage is supplied during the on state, and the ultrahigh-frequency voltage is turned off during the off state to establish a duty ratio.

5. The pulse-plasma etching apparatus of claim 4, wherein the duration of the on state is 1 to 100 microseconds, and the duration of the off state is 1 to 100 microseconds.

6. The pulse-plasma etching apparatus of claim 4, further comprising a gas exhaust unit and an additional gas source connected to the processing chamber, wherein the processing gas is removed from the processing chamber by the gas exhaust unit and an additional gas is introduced into the processing chamber by the additional gas source when the ultrahigh-frequency voltage is turned off

7. The pulse-plasma etching apparatus of claim 6, wherein the additional gas is selected from the group consisting of Ar, He, Xe, N₂, H₂ and the combination thereof.

8. The pulse-plasma etching apparatus of claim 1, wherein the lower electrode plate includes a chuck for holding a substrate.

9. The pulse-plasma etching apparatus of claim 1, wherein the first ultrahigh RF power supply continuously supplies an upper ultrahigh RF power to the upper electrode plate during a plasma etching process.

10. The pulse-plasma etching apparatus of claim 1, further comprising a DC power supply electrically connected to the upper electrode plate for continuously supplying a DC power to the upper electrode plate during the plasma etching process.

11. The pulse-plasma etching apparatus of claim 8, wherein the substrate, including a low-κ dielectric layer, is etched at a temperature greater than 20° C.

12. A pulse-plasma etching method, comprising the steps of:
forming a mask on a substrate, wherein the mask has a pattern;
placing the substrate with the mask into a plasma etching apparatus, wherein the plasma etching apparatus comprises a container having an upper wall and a lower wall, an upper electrode plate disposed on the upper wall, and a lower electrode plate disposed on the lower wall and holding the substrate;
introducing a processing gas into a processing chamber defined by the upper wall and the lower wall;
supplying an upper ultrahigh RF power and a DC power to the upper electrode plate; and
supplying an ultrahigh-frequency voltage to the lower electrode plate to discontinuously etch the substrate.

13. The pulse-plasma etching method of claim 12, wherein the substrate has a low-κ dielectric layer, the mask is blanketed over the low-κ dielectric layer, and the substrate is etched at a temperature greater than 20° C.

14. The pulse-plasma etching method of claim 12, wherein the mask is a carbon hard mask.

15. The pulse-plasma etching method of claim 12, wherein the processing gas includes an etch gas and a deposition gas.

16. The pulse-plasma etching method of claim 12, further comprising a step of supplying a lower ultrahigh RF power to the lower electrode plate.

17. The pulse-plasma etching method of claim 12, wherein the ultrahigh-frequency voltage is alternately switched between on and off states, the ultrahigh-frequency voltage is supplied during the on state, and the ultrahigh-frequency voltage is turned off during the off state to establish a duty ratio.

18. The pulse-plasma etching method of claim 17, wherein the duration of the on state is 1 to 100 microseconds, and the duration of the off state is 1 to 100 microseconds.

19. The pulse-plasma etching method of claim 12, wherein the processing gas is removed from the processing chamber and an additional gas is introduced into the processing chamber when the ultrahigh-frequency voltage is turned off.

20. The pulse-plasma etching method of claim 19, wherein the additional gas is selected from the group consisting of Ar, He, Xe, N₂, H₂ and the combination thereof.
